(19) United States
(12) Patent Application Publication
(10) Pub. No.: US 2025/0119079 A1
(43) Pub. Date: Apr. 10, 2025

(54) ELECTROSTATIC CHUCK

(71) Applicant: TOTO LTD., Fukuoka (JP)

(72) Inventors: Kouta KOBAYASHI, Fukuoka (JP); Masafumi IKEGUCHI, Fukuoka (JP); Yutaka MOMIYAMA, Fukuoka (JP)

(73) Assignee: TOTO LTD., Fukuoka (JP)

(21) Appl. No.: 18/891,449

(22) Filed: Sep. 20, 2024

(30) Foreign Application Priority Data
Oct. 10, 2023 (JP) 2023-175473

(51) Int. Cl. H02N 13/00; B23Q 3/15

(52) U.S. Cl. CPC H02N 13/00; B23Q 3/15

(57) ABSTRACT

An electrostatic chuck (10) includes a dielectric substrate (100), a base plate (200) formed of a metal material, and a bonding layer (300) bonding the dielectric substrate (100) and the base plate (200). At least a portion of the base plate (200) facing the bonding layer (300) is covered with a ceramic film (231), and a surface of the ceramic film (231) is a bonded surface (S). The bonded surface (S) satisfies at least one of a first condition: arithmetic average height (Sa)≤1.5 μm or a second condition: root mean square height (Sq)≤2.0 μm, and at least one of a third condition: maximum valley depth (Sv)≥20.0 μm or a fourth condition: maximum height (Sz)≥20.0 μm.

### CROSS-REFERENCE TO RELATED APPLICATION

This application is based upon and claims the benefit of priority from Japanese Patent Application No. 2023-175473 filed on Oct. 10, 2023, the entire contents of which are incorporated herein by reference.

### TECHNICAL FIELD

The present invention relates to an electrostatic chuck.

### BACKGROUND ART

A semiconductor manufacturing device, such as an etching device, includes an electrostatic chuck as a device for adsorbing and holding a substrate, such as a silicon wafer, to be processed. As described in Patent Document 1 below, the electrostatic chuck includes a dielectric substrate including an adsorbing electrode, and a base plate supporting the dielectric substrate, and has a configuration in which the dielectric substrate and the base plate are bonded to each other. The dielectric substrate and the base plate are bonded to each other via a bonding layer which is, for example, a silicone adhesive. A voltage applied to the adsorbing electrode causes an electrostatic force to be generated so that the adsorbing electrode adsorbs and holds the substrate placed on the dielectric substrate.

### CITATION LIST

### Patent Literature

Patent Document 1: JP H04-287344 A

### SUMMARY OF INVENTION

### Technical Problem

When the semiconductor manufacturing device performs processing such as etching, a temperature of the substrate rises due to exposure to plasma, which raises a temperature of the dielectric substrate as well. On the other hand, a low-temperature coolant is supplied to the base plate, and thus a temperature of the base plate may decrease to −60° C. or lower. As a result of such temperature changes of each component associated with the processing of the substrate, as well as factors such as a temperature difference between the dielectric substrate and the base plate, a large thermal stress is applied to the bonding layer and the vicinity thereof.

When part of the bonding layer peels from a surface of the base plate due to thermal stress, the surface of the base plate is exposed. As a result, there is a possibility that dielectric breakdown will occur between the exposed portion and a member around the exposed portion.

Note that a portion of the surface of the base plate exposed by such peeling of the bonding layer may be covered with a ceramic film formed in advance by thermal spraying. However, such a ceramic film alone may not be able to prevent dielectric breakdown when the bonding layer peels.

The present invention has been made in view of such problems, and an object thereof is to provide an electrostatic chuck that can suppress the occurrence of dielectric breakdown in the vicinity of a bonding layer.

### Solution to Problem

To solve the problem described above, an electrostatic chuck according to the present invention includes a dielectric substrate, a base plate formed of a metal material, and a bonding layer bonding the dielectric substrate and the base plate. At least a portion of the base plate facing the bonding layer is covered with a ceramic film, and a surface of the ceramic film is a bonded surface.

The bonded surface satisfies at least one of a first condition or a second condition below:
first condition: arithmetic average height (Sa)≤1.5 μm,
second condition: root mean square height (Sq)≤2.0 μm, and
at least one of a third condition or a fourth condition below:
third condition: maximum valley depth (Sv)≥20.0 μm,
fourth condition: maximum height (Sz)≥20.0 μm.

Among the conditions described above to be satisfied by a surface shape of the bonded surface, the first condition and the second condition are both conditions specifying that the bonded surface is smooth. When the bonded surface is a smooth surface to the extent that at least one of the first condition or the second condition is satisfied, a thickness of the bonding layer is substantially uniform as a whole, and a thermal resistance of the bonding layer is also substantially uniform. This makes it possible to make an in-plane temperature distribution of the substrate during processing uniform.

On the other hand, the third condition and the fourth condition are both conditions specifying that relatively deep recesses are formed in the bonded surface. When the recesses are formed in the bonded surface to such an extent that at least one of the third condition or the fourth condition is satisfied, uncured adhesive enters the recesses at the time of bonding the dielectric substrate and the base plate, and is subsequently cured. This increases a so-called “anchor effect”, thereby increasing a bonding strength between the bonding layer and the bonded surface (that is, ceramic film).

Thus, in the electrostatic chuck having the configuration described above, by forming the shape of the bonded surface of the ceramic film so as to satisfy the predetermined conditions, it is possible to sufficiently increase the bonding strength between the bonding layer and the bonded surface by the anchor effect while suppressing variation in a thickness of the bonding layer.

In a case in which a large thermal stress is applied to the bonding layer and the vicinity thereof during the processing of the substrate, the bonding layer peels at an interface on the dielectric substrate side before peeling at an interface on the ceramic film side, or breakage occurs inside the bonding layer. In either case, the entire bonded surface of the ceramic film remains covered with the bonding layer, and thus is not exposed to the outside due to the peeling of the bonding layer. This makes it possible to sufficiently suppress the occurrence of dielectric breakdown in the vicinity of the bonding layer, specifically, dielectric breakdown through the exposed portion of the ceramic film.

### Advantageous Effects of Invention

According to the present invention, it is possible to provide an electrostatic chuck that can suppress the occurrence of dielectric breakdown in the vicinity of a bonding layer.

### BRIEF DESCRIPTION OF DRAWINGS

FIG. 1 is a cross-sectional view schematically illustrating a configuration of an electrostatic chuck according to an embodiment.

FIG. 2 is a view schematically illustrating a cross-sectional shape of a bonded surface of a ceramic film.

FIG. 3A is a view for explaining peeling of a bonding layer.

FIG. 3B is a view for explaining peeling of a bonding layer.

### DESCRIPTION OF EMBODIMENTS

Hereinafter, embodiments will be described with reference to the accompanying drawings. To facilitate understanding of the description, similar components in the drawings are denoted by like reference signs to the extent possible, and duplicate description thereof will be omitted.

An electrostatic chuck 10 according to the present embodiment adsorbs and holds a substrate W to be processed by an electrostatic force inside a semiconductor manufacturing device (not illustrated), such as an etching device. The substrate W is, for example, a silicon wafer. The electrostatic chuck 10 may be used in a device other than a semiconductor manufacturing device.

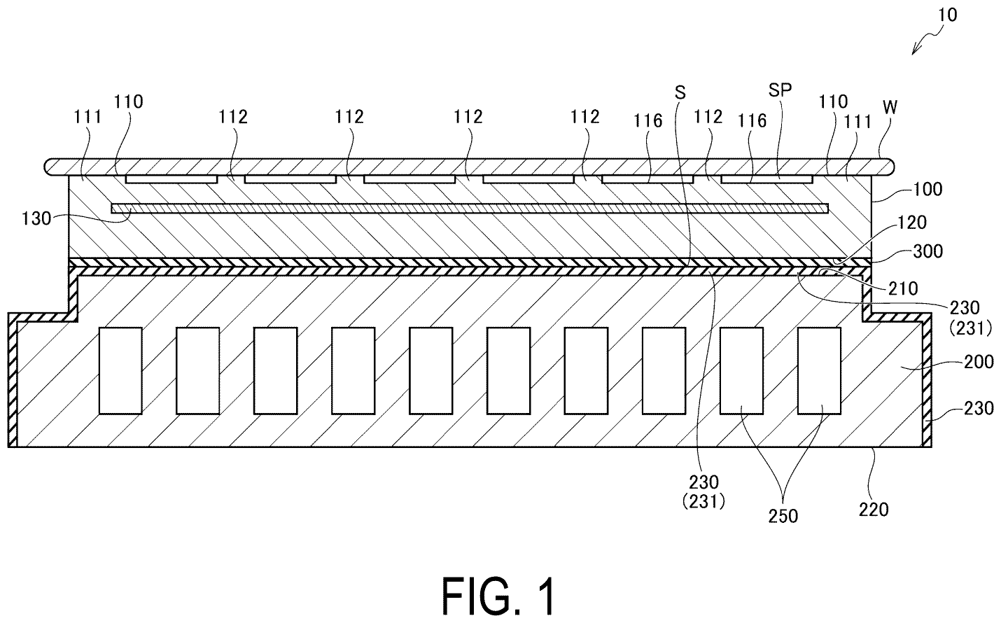

FIG. 1 illustrates, in a schematic cross-sectional view, a configuration of the electrostatic chuck 10 in a state of adsorbing and holding the substrate W. The electrostatic chuck 10 includes a dielectric substrate 100, a base plate 200, and a bonding layer 300.

The dielectric substrate 100 is a substantially disk-shaped member made of a ceramic sintered body. The dielectric substrate 100 includes, for example, aluminum oxide (Al₂O₃) having high purity, but may include other materials. The purity, type, additives, and the like of the ceramic of the dielectric substrate 100 can be set as appropriate in consideration of plasma resistance and other characteristics required of the dielectric substrate 100 in the semiconductor manufacturing device.

A surface 110 of the dielectric substrate 100 on an upward side in FIG. 1 is a “placement surface” on which the substrate W is placed. Further, a surface 120 of the dielectric substrate 100 on a downward side in FIG. 1 is a surface to be bonded to the base plate 200 via the bonding layer 300 described below.

An adsorbing electrode 130 is embedded inside the dielectric substrate 100. The adsorbing electrode 130 is a layer having a thin flat plate shape, formed of a metal material such as tungsten, and is built into the dielectric substrate 100 in a state of being parallel to the surface 110. As a material of the adsorbing electrode 130, molybdenum, platinum, palladium, or the like may be used in addition to or instead of tungsten. A voltage applied to the adsorbing electrode 130 from an external source via a power supply path (not illustrated) causes an electrostatic force to be generated between the surface 110 and the substrate W so that the adsorbing electrode 130 adsorbs and holds the substrate W. As the configuration of the power supply path, various known configurations can be adopted. Only one adsorbing electrode 130 may be provided as a so-called “unipolar” electrode, as in the present embodiment, or two adsorbing electrodes 130 may be provided as so-called “bipolar” electrodes.

As illustrated in FIG. 1, a space SP is formed between the dielectric substrate 100 and the substrate W. When processing such as etching is performed in the semiconductor manufacturing device, helium gas for temperature adjustment is supplied from an external source to the space SP via a gas hole (not illustrated). When the helium gas is present between the dielectric substrate 100 and the substrate W, the thermal resistance between the dielectric substrate 100 and the substrate W is adjusted such that the temperature of the substrate W is maintained at an appropriate temperature. Note that the gas used for temperature adjustment that is supplied to the space SP may be a gas which is different from helium.

On the surface 110 that is the placement surface, a sealing ring 111, dots 112, and the like are provided, and the space SP described above is formed around them.

The sealing ring 111 is a wall defining the space SP at a position corresponding to an outermost perimeter. An upper end surface of the sealing ring 111 is part of the surface 110 and abuts against the substrate W. Note that a plurality of the sealing rings 111 may be provided, dividing the space SP. With such a configuration, it is possible to individually adjust the pressure of the helium gas in each space SP and make a surface temperature distribution of the substrate W during processing close to uniform.

A section denoted by reference sign “116” in FIG. 1 is a bottom surface of the space SP. Hereinafter, this section is also referred to as “bottom surface 116”. The sealing ring 111 is formed as a result of recessing part of the surface 110, to the position of the bottom surface 116, along with the dots 112 described next.

The dot 112 is a circular projection protruding from the bottom surface 116. A plurality of the dots 112 are provided and arranged dispersed in a substantially uniform manner on the placement surface of the dielectric substrate 100. An upper end of each dot 112 forms part of the surface 110 and abuts against the substrate W. With the plurality of dots 112 being provided, deflection of the substrate W is suppressed.

The base plate 200 is a substantially disc-shaped member that supports the dielectric substrate 100. The base plate 200 is formed of a metal material such as aluminum. A surface 210 of the base plate 200 on the upward side in FIG. 1 is a portion facing the bonding layer 300. However, in the present embodiment, the surface 210 and the bonding layer 300 are not directly bonded to each other, and a ceramic film 230 is interposed therebetween.

The ceramic film 230 is an insulating film formed covering a surface of the base plate 200. As the ceramic film 230, for example, an alumina film formed by thermal spraying can be used. By covering the surface of the base plate 200 with the ceramic film 230, a withstand voltage of the base plate 200 is increased.

The ceramic film 230 covers not only the surface 210 of the base plate 200 but also side surfaces and the like connected to the surface 210. Of the surface of the base plate 200, only a surface 220 on a side opposite to the surface 210 is not covered with the ceramic film 230. Instead of such a form, a configuration may be adopted in which only the surface 210 is covered with the ceramic film 230.

A portion of the ceramic film 230 covering the surface 210 is hereinafter also referred to as “ceramic film 231”. An outward surface of the ceramic film 231 is a surface bonded to the dielectric substrate 100 via the bonding layer 300. This surface is hereinafter also referred to as “bonded surface S”.

Thus, in the present embodiment, at least a portion (surface 210) of the base plate 200 facing the bonding layer 300 is covered with the ceramic film 231, and the surface of the ceramic film 231 is the bonded surface S.

A coolant flow channel 250 through which a coolant flows is formed inside the base plate 200. When processing such as etching is performed on the semiconductor manufacturing device, the coolant is supplied from an external source to the coolant flow channel 250, thereby cooling the base plate 200. Heat generated in the substrate W during processing is transferred to the coolant via the helium gas in the space SP, the dielectric substrate 100, and the base plate 200, and is exhausted to the outside together with the coolant.

The bonding layer 300 is a layer provided between the dielectric substrate 100 and the base plate 200, and bonds the dielectric substrate 100 and the base plate 200 to each other. The bonding layer 300 is formed by curing an adhesive made of an insulating material. In the present embodiment, a silicone adhesive is used as the adhesive described above. However, the bonding layer 300 may be formed by curing another type of adhesive. In any case, preferably, a material having a thermal conductivity as high as possible may be used as the material of the bonding layer 300 to reduce a thermal resistance between the dielectric substrate 100 and the base plate 200.

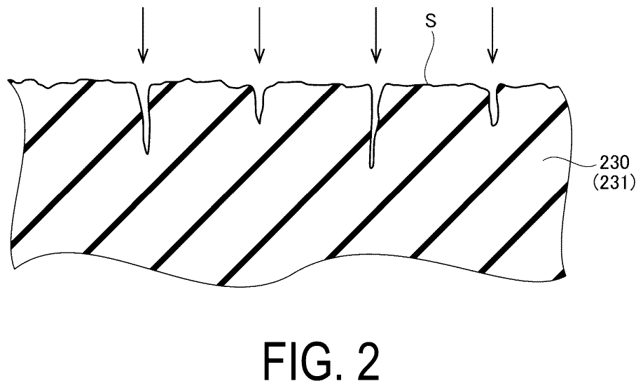

In the present embodiment, a bonding strength between the bonding layer 300 and the bonded surface S is increased by devising a shape of the bonded surface S of the ceramic film 231. FIG. 2 schematically illustrates a cross-sectional shape of the bonded surface S and the vicinity thereof in the ceramic film 231. The ceramic film 231 according to the present embodiment is a film formed by thermal spraying, and thus countless irregularities are formed on the bonded surface S. The bonded surface S is formed to satisfy at least one of the following first condition or second condition.
First condition: Arithmetic average height (Sa)≤1.5 μm
Second condition: Root mean square height (Sq)≤2.0 μm

The “arithmetic average height (Sa)” of the first condition is obtained by expanding an arithmetic average height (Ra) from a line to a plane. The arithmetic average height (Sa) can be calculated as an absolute average value of a difference in height at each position of the bonded surface S with respect to an average plane of the bonded surface S. The “root mean square height (Sq)” of the second condition can be calculated as the standard deviation of the height (distance) at each position of the bonded surface S with respect to the average plane of the bonded surface S. As respective definitions and measurement methods of the arithmetic average height (Sa) and the root mean square height (Sq) described above, those specified in ISO 25178 can be employed.

The first condition and the second condition described above are both conditions specifying that the bonded surface S is a smooth surface to some extent. The bonded surface S may satisfy both the first condition and the second condition, or may satisfy only one of the first condition or the second condition. When the bonded surface S is a smooth surface to the extent that at least one of the first condition or the second condition is satisfied, a thickness of the bonding layer 300 immediately above the bonded surface S is substantially uniform as a whole, and a thermal resistance of the bonding layer 300 is also substantially uniform. With this configuration, it is possible to make an in-plane temperature distribution of the substrate W during processing uniform.

The bonded surface S is further formed to satisfy at least one of the following third condition or fourth condition.
Third condition: Maximum valley depth (Sv)≥20.0 μm
Fourth condition: Maximum height (Sz)≥20.0 μm

The “maximum valley depth (Sv)” of the third condition can be calculated as the absolute value of a minimum value of the height at each position of the bonded surface S with respect to the average plane of the bonded surface S. The “maximum height (Sz)” of the fourth condition can be calculated as a distance from a highest point to a lowest point among the respective positions of the bonded surface S (distance in a direction perpendicular to the average plane of the bonded surface S). As respective definitions and measurement methods of the maximum valley depth (Sv) and the maximum height (Sz) described above, those specified in ISO 25178 can be employed.

The third condition and the fourth condition described above are both conditions specifying that relatively deep recesses are formed in the bonded surface S. In the example of FIG. 2, such recesses are formed in the bonded surface S at each position indicated by an arrow. In view of the fact that the bonded surface S satisfies the first condition or the second condition, in many cases, a plurality of the recesses are formed scattered apart from each other.

When the recesses are formed in the bonded surface S to such an extent that at least one of the third condition or the fourth condition is satisfied, uncured adhesive enters the recesses at the time of bonding the dielectric substrate 100 and the base plate 200, and is subsequently cured. This increases a so-called “anchor effect”, thereby increasing the bonding strength between the bonding layer 300 and the bonded surface S.

Thus, in the electrostatic chuck 10 according to the present embodiment, by forming the shape of the bonded surface S of the ceramic film 231 into a shape that satisfies the conditions described above, it is possible to sufficiently increase the bonding strength between the bonding layer 300 and the bonded surface S by the anchor effect while suppressing variation in the thickness of the bonding layer 300.

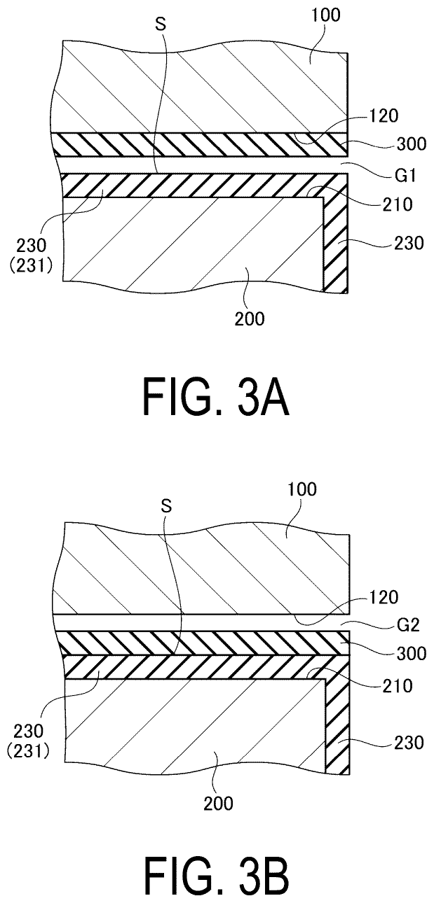

In a case in which a large thermal stress is applied to the bonding layer 300 and the vicinity thereof during the processing of the substrate W, there is a concern that the bonding layer 300 will locally peel at the interface on the dielectric substrate 100 side or the ceramic film 231 side. FIG. 3A schematically illustrates an example of a case in which the bonding layer 300 peels at the interface on the ceramic film 231 side. In this case, a minute gap G1 is formed between the bonding layer 300 and the ceramic film 231, and thus part of the bonded surface S is exposed to the outside through the gap G1. As a result, there is a possibility that dielectric breakdown will occur between that portion and a peripheral member (e.g., part of the semiconductor manufacturing device).

Therefore, in the electrostatic chuck according to the present embodiment, the bonding strength between the bonding layer 300 and the bonded surface S is increased by forming the bonded surface S to satisfy each condition described above. When a large thermal stress is applied to the bonding layer 300 and the vicinity thereof, the bonding layer 300 of the present embodiment peels at the interface on the dielectric substrate 100 side before peeling at the interface on the ceramic film 231 side, or breakage occurs inside the bonding layer 300. FIG. 3B schematically illustrates an example in which the bonding layer 300 peels at the interface on the dielectric substrate 100 side. In this case, although a minute gap G2 is formed between the bonding layer 300 and the dielectric substrate 100, the entire bonded surface S of the ceramic film 231 is covered with the bonding layer 300. Even in a case in which the bonding layer 300 breaks internally, a similar state is obtained, and thus the bonded surface S of the ceramic film 231 is not exposed to the outside by the peeling of the bonding layer 300. This makes it possible to sufficiently suppress the occurrence of dielectric breakdown in the vicinity of the bonding layer 300, more specifically, dielectric breakdown through the exposed portion of the ceramic film 231.

Note that, when the electrostatic chuck 10 is attached to the semiconductor manufacturing device, a portion of the ceramic film 230 other than the ceramic film 231 is covered with another structural member (e.g., a focus ring) from the outside. For this reason, there is a low possibility that dielectric breakdown will occur via that portion.

As values of the maximum valley depth (Sv) of the third condition and/or the maximum height (Sz) of the fourth condition increase, the bonding strength between the bonding layer 300 and the bonded surface S due to the anchor effect can be further increased. However, when these values are too large, the recesses in the bonded surface S further deepen and porosity of the ceramic film 230 increases, resulting in the possibility that rather dielectric breakdown through the ceramic film 230 will likely occur. There is also a concern that helium gas will leak through the ceramic film 230.

Therefore, preferably, the bonded surface S is formed to further satisfy at least one of the following fifth condition or sixth condition.
Fifth condition: Maximum valley depth (Sv)≤100.0 μm
Sixth condition: Maximum height (Sz)≤100.0 μm

As long as the bonded surface S is formed as described above, the recesses do not become excessively deep, and thus it is possible to sufficiently suppress the occurrence of dielectric breakdown through the ceramic film 230 and the like.

Each parameter of the arithmetic average height (Sa) of the first condition, the root mean square height (Sq) of the second condition, the maximum valley depth (Sv) of the third condition, and the maximum height (Sz) of the fourth condition is obtained by measuring an entire predetermined region of the bonded surface S as the “surface” by a roughness measuring device. As the “predetermined region”, preferably, a region having an area of 350000 μm² or greater may be set as a measurement target. By forming the shape of the bonded surface S into a shape that satisfies the first condition or the like while measuring each of the above parameters with setting such a region as a target, it is possible to sufficiently suppress the occurrence of dielectric breakdown without the influence of measurement errors.

In the technical field of forming a ceramic film by thermal spraying, it is known that the porosity of the ceramic film changes depending on various film forming conditions. For example, the porosity of the ceramic film to be formed varies depending on the thermal spraying method, such as high-velocity flame spraying or plasma spraying, and/or a particle size of the thermal spraying material. By appropriately selecting such film forming conditions, it is possible to form such a ceramic film 231 that satisfies the third condition and/or the fourth condition, and the fifth condition and/or the sixth condition. Subsequently, it is possible to form such a shape that satisfies the first condition and/or the second condition by polishing the bonded surface S or the like, as necessary.

Embodiments have been described above with reference to specific examples. However, the present disclosure is not limited to these specific examples. Those skilled in the art can suitably modify these specific examples, and such modifications are also encompassed within the scope of the present disclosure as long as they include the features of the present disclosure. Each element included in each of the specific examples described above and the arrangement, condition, shape, and the like thereof are not limited to those described, and can be changed as appropriate. The combinations of the elements in each of the specific examples described above can be changed as appropriate, as long as no technical contradiction occurs.

1. An electrostatic chuck comprising:
a dielectric substrate;
a base plate formed of a metal material; and
a bonding layer bonding the dielectric substrate and the base plate, wherein
at least a portion of the base plate facing the bonding layer is covered with a ceramic film, and a surface of the ceramic film is a bonded surface, and
the bonded surface satisfies
at least one of a first condition or a second condition below:
first condition: arithmetic average height (Sa)≤1.5 μm,
second condition: root mean square height (Sq)≤2.0 μm, and
at least one of a third condition or a fourth condition below:
third condition: maximum valley depth (Sv)≥20.0 μm,
fourth condition: maximum height (Sz)≥20.0 μm.

2. The electrostatic chuck according to claim 1, wherein
the bonded surface satisfies at least one of a fifth condition or a sixth condition below:
fifth condition: maximum valley depth (Sv)≤100.0 μm,
sixth condition: maximum height (Sz)≤100.0 μm.

3. The electrostatic chuck according to claim 1, wherein
the ceramic film is a film formed by thermal spraying.

4. The electrostatic chuck according to claim 1, wherein
the arithmetic average height (Sa) of the first condition, the root mean square height (Sq) of the second condition, the maximum valley depth (Sv) of the third condition, and the maximum height (Sz) of the fourth condition are each a value obtained by measuring an entire region of the bonded surface having an area of 350000 μm² or greater.
